(19) United States
(12) Patent Application Publication
(10) Pub. No.: US 2010/0126419 A1
(43) Pub. Date: May 27, 2010

(54) SUSCEPTOR FOR CVD APPARATUS AND CVD APPARATUS INCLUDING THE SAME

(75) Inventors: Sung Hwan JANG, Yongin (KR); Sang Duk Yoo, Seongnam (KR); Ho IL Jung, Suwon (KR); Chul Kyu Lee, Seoul (KR); Motonobu Takeya, Seoul (KR)

Correspondence Address: MCDERMOTT WILL & EMERY LLP, 600 13TH STREET, N.W., WASHINGTON, DC, 20005-3096, US

(73) Assignee: SAMSUNG LED CO., LTD.

(21) Appl. No.: 12/575,841

(22) Filed: Oct. 8, 2009

(30) Foreign Application Priority Data
Nov. 27, 2008 (KR) 10-2008-0119185

(51) Int. Cl. C23C 16/458; C23C 16/00

(52) U.S. Cl. 118/730

(57) ABSTRACT

Provided are a susceptor and a chemical vapor deposition (CVD) apparatus including the susceptor. The susceptor has a simple structure and is configured to prevent bending of a substrate for uniformly heating the substrate and maintain wavelength uniformity of an epitaxial layer formed on the substrate.

### CROSS-REFERENCE TO RELATED APPLICATIONS

This application claims the priority of Korean Patent Application No. 10-2008-0119185 filed on Nov. 27, 2008, in the Korean Intellectual Property Office, the disclosure of which is incorporated herein by reference.

### BACKGROUND OF THE INVENTION

1. Field of the Invention

The present invention relates to an apparatus for performing a high-temperature chemical vapor deposition (CVD) process on a substrate, and more particularly, to a susceptor having a structure for uniformly heating a substrate placed thereon, and a CVD apparatus including the susceptor.

2. Description of the Related Art

Recently, devices such as small and high-performance semiconductor devices and high-power light emitting devices (LEDs) are increasingly required in various industrials. Therefore, there is an increasing need for a chemical vapor deposition (CVD) apparatus that can be used for mass-producing such devices without reducing the quality or performance of the devices.

Generally, a CVD apparatus is used to grow a thin epitaxial layer on a substrate by using chemical reaction between a heated top side of the substrate and reaction gas supplied to the inside of a reaction chamber where the substrate is placed.

The epitaxial layer grown on the substrate should have a uniform thickness all over the area of the substrate, and for this, the substrate should be uniformly heated.

However, a substrate is increased in thickness with an increase in its size, and the substrate may be bent (bowing effect) and cracked due to the difference in stress caused by the increase in thickness of the substrate.

If a substrate is bent, an inner region of the substrate may be heated to a relatively higher temperature than an outer region of the substrate because the inner region makes contact with the bottom side of a pocket while the outer region of the substrate is spaced apart from the bottom side of the pocket.

In this case, a concentration of a material growing on the substrate varies due to the difference in temperature between the inner and outer regions of the substrate. Therefore, when devices such as LED are formed on the substrate, the substrate may have non-uniform wavelength characteristics, and it may be difficult to perform the subsequent processes, thereby adversely affecting the manufacturing efficiency and product quality.

To prevent the bowing effect of a large substrate, various attempts such as patterning of the substrate and modification of a susceptor are being made.

### SUMMARY OF THE INVENTION

An aspect of the present invention provides a susceptor having a simple structure and configured to prevent bending of a substrate for uniformly heating the substrate and maintain wavelength uniformity of an epitaxial layer formed on the substrate, and a chemical vapor deposition (CVD) apparatus including the susceptor.

According to an aspect of the present invention, there is provided a susceptor for a CVD apparatus, the susceptor including: a rotary part configured to be rotated through a rotation shaft connected to a driving device; and at least one pocket disposed at a top side of the rotary part for receiving a substrate, wherein the pocket includes a block part protruded upward from a bottom side of the pocket on which the substrate is placed, the block part being protruded at a position corresponding to a position of a groove, which is formed in a bottom side of the substrate for distributing stress uniformly along the substrate.

The pocket may include one or more block parts according to the number and positions of grooves formed in the bottom side of the substrate.

The block part of the pocket may have a ring shape.

The block part of the pocket may include a plurality of blocks arranged at predetermined intervals in a ring shape.

The pocket may be separable from the rotary part and rotatable relative to the rotary part.

The pocket may further include a fixing clip configured to fix the substrate placed at the pocket for preventing escaping of the substrate when the pocket is rotated.

The block part of the pocket may have a shape corresponding to that of the groove of the substrate for coupling with the groove.

According to another aspect of the present invention, there is provided a CVD apparatus including: a reaction chamber to which reaction gas is supplied through a gas supply unit for performing a deposition process; a substrate to which the reaction gas is supplied for depositing an epitaxial layer on a top side of the substrate, the substrate including a groove in a bottom side thereof for uniformly distributing stress when the epitaxial layer is deposited; a pocket at which the substrate is placed, the pocket including a block part protruded upward from a bottom side of the pocket that makes contact with the bottom side of the substrate, the block part being protruded at a position corresponding to a position of the groove of the substrate; a susceptor including the pocket at a top side thereof; and a heating unit disposed at a bottom side of the susceptor for heating the substrate.

The pocket may include one or more block parts according to the number and positions of grooves formed in the bottom side of the substrate.

The block part of the pocket may have a ring shape or include a plurality of blocks arranged at predetermined intervals in a ring shape.

The pocket may be separable from the susceptor and rotatable relative to the susceptor.

The block part of the pocket may have a shape corresponding to that of the groove of the substrate for coupling with the groove.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a plan view illustrating a susceptor for a chemical vapor deposition (CVD) apparatus according to an embodiment of the present invention;

FIG. 1B is a sectional view taken along line X-X′ of FIG. 1A;

FIG. 2A is an enlarged perspective view illustrating pockets and block parts of the susceptor according to an exemplary embodiment of the present invention;

FIG. 2B is an enlarged perspective view illustrating modification versions of the pockets and the block parts of FIG. 2A according to another exemplary example of the present invention;

FIG. 3 is a sectional view illustrating the pocket and the block part depicted in FIGS. 2A and 2B;

FIGS. 4A and 4B are sectional views illustrating modification versions of the pocket and the block part of the susceptor according to other exemplary embodiments of the present invention;

FIG. 5 is a sectional view illustrating a modification version of the pocket of the susceptor according to another embodiment of the present invention;

FIG. 6A is a sectional view illustrating a CVD apparatus including a susceptor according to an exemplary embodiment of the present invention; and

FIG. 6B is a sectional view illustrating a CVD apparatus including a susceptor according to another exemplary embodiment of the present invention.

### DETAILED DESCRIPTION OF THE PREFERRED EMBODIMENT

A susceptor for a chemical vapor deposition (CVD) apparatus and a CVD apparatus including the susceptor will now be described in detail with reference to the accompanying drawings according to exemplary embodiments of the present invention.

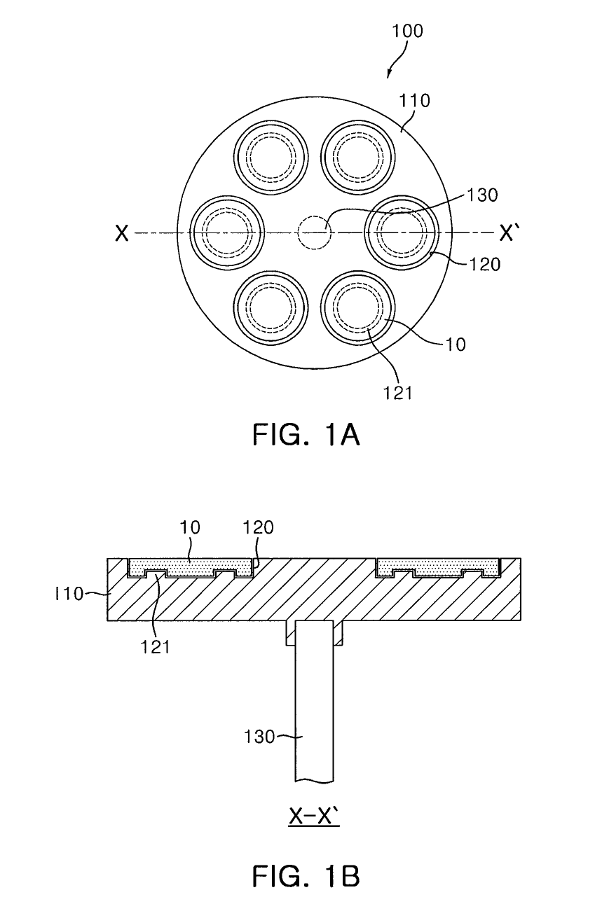

FIG. 1A is a plan view illustrating a susceptor 100 for a chemical vapor deposition (CVD) apparatus according to an embodiment of the present invention, and FIG. 1B is a sectional view taken along line X-X′ of FIG. 1A.

Referring to FIGS. 1A and 1B, according to an embodiment of the present invention, the susceptor 100 for a CVD apparatus includes a rotary part 110, pockets 120, and a rotation shaft 130.

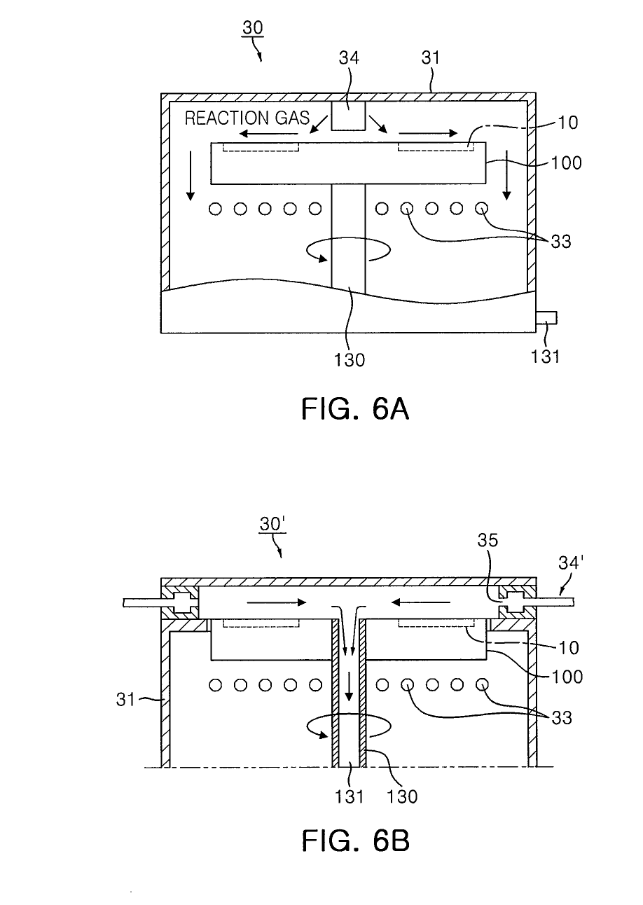

The rotary part 110 is a rotary member formed of graphite coated with carbon or silicon carbide (SiC). The rotary part 110 has a disk shape such that the rotary part 110 can be easily rotated in a reaction chamber 31 (refer to FIG. 6) to which reaction gas is supplied.

At the top side of the rotary part 110, the pockets 120 are regularly arranged on the same plane around the rotation center of the rotary part 110 along the circumferential direction. Substrates 10 may be placed in the pockets 120 for chemically depositing a metal compound on the substrates 10.

That is, while simultaneously rotating the substrates 10 placed in the pockets 120 of the rotary part 110, epitaxial layers may be simultaneously grown on the substrates 10.

The rotation shaft 130 is coupled to the bottom side of the rotary part 110, and a driving unit (not shown) is connected to the rotation shaft 130. Therefore, when the rotation shaft 130 is rotated in a predetermined direction by the driving unit, the rotary part 110 is rotated together with the rotation shaft 130 in the predetermined direction.

The number of the pockets 120 may be one or more. Substrates 10 may be placed in the pockets 120 for growing epitaxial layers on the substrates 10.

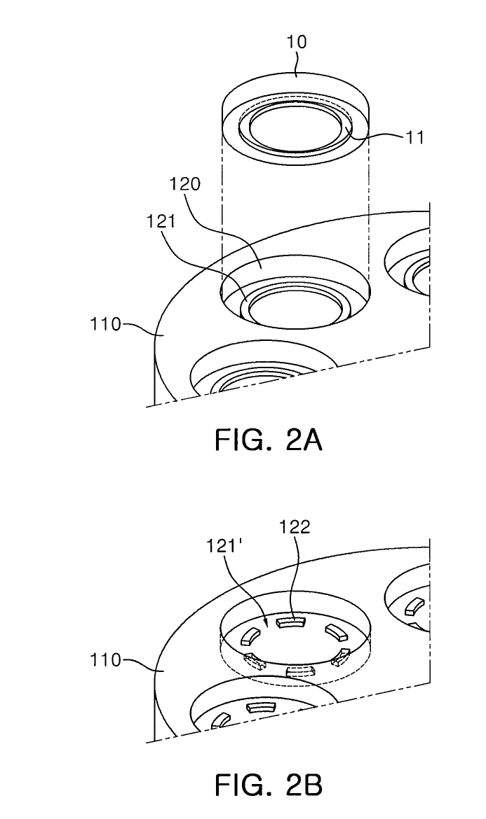

The pockets 120 will now be described in more detail with reference to FIGS. 2A through 5.

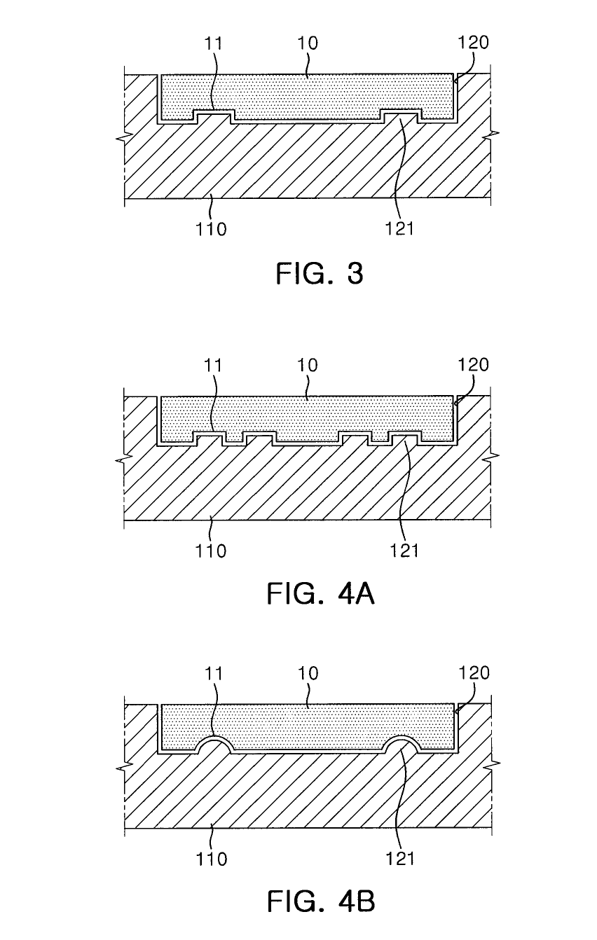

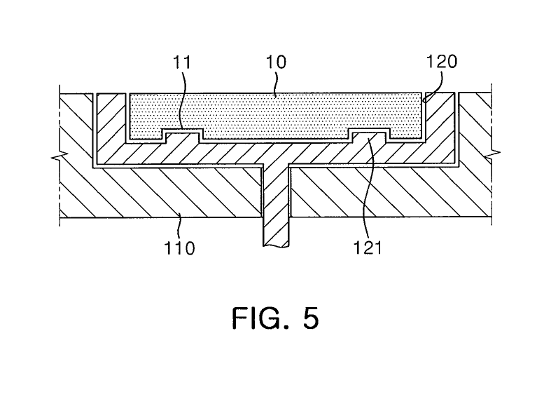

FIG. 2A is an enlarged perspective view illustrating the pockets 120 and block parts 121 of the susceptor 100 according to an exemplary embodiment of the present invention; FIG. 2B is an enlarged perspective view illustrating modification versions of the pockets 120 and the block parts 121 of FIG. 2A according to another exemplary example of the present invention; FIG. 3 is a sectional view illustrating the pocket 120 and the block part 121 depicted in FIGS. 2A and 2B; FIGS. 4A and 4B are sectional views illustrating modification versions of the pocket 120 and the block part 121 of the susceptor 100 according to other exemplary embodiments of the present invention; and FIG. 5 is a sectional view illustrating a modification version of the pocket 120 of the susceptor 100 according to another embodiment of the present invention.

Referring to FIGS. 2A and 2B, each of the pockets 120 may have a shape corresponding to a disk-shaped substrate 10. The pocket 120 may have a diameter larger than that of the substrate 10 so as to easily place the substrate 10 in the pocket 120 and take the substrate 10 out of the pocket 120.

The pocket 120 includes the block part 121. The block part 121 protrudes upward from the bottom side of the pocket 120 at a position corresponding to a groove 11 formed in the bottom side of the substrate 10 for uniform distribution of stress.

For example, when a gallium nitride (GaN) epitaxial layer is growing on a sapphire substrate 10, the sapphire substrate 10 may be bent (bowing effect) due to the difference in lattice constants and thermal expansion coefficients between the GaN epitaxial layer and the sapphire substrate 10. The bowing effect becomes serious when the size of the sapphire substrate 10 is large. For example, the bowing effect becomes more serious when the sapphire substrate 10 is a large substrate such as a 6-inch or 8-inch substrate than when the sapphire substrate 10 is a small substrate such as a 4-inch substrate.

Therefore, it is necessary to minimize the stress distribution difference between the sapphire substrate 10 and the GaN epitaxial layer to reduce bending of the sapphire substrate 10. To reduce bending of the sapphire substrate 10, a groove 11 may be formed in the bottom side of the sapphire substrate 10.

In the case where a substrate 10 having a groove 11 in its bottom side is placed in the pocket 120 with the bottom side of the substrate 10 being in contact with the bottom side of the pocket 120, an air cavity is formed between the substrate 10 and the pocket 120 due to the groove 11, and thus it is difficult to heat the substrate 10 uniformly by using a heating unit 33 (refer to FIG. 6) disposed under the susceptor 100.

That is, although a region of the substrate 10 making contact with the bottom side of the pocket 120 may be easily heated to a high temperature owing to a high heat transfer rate, a cavity region of the substrate 10 where the groove 11 is formed may not be easily heated to a high temperature due to a low heat transfer rate.

Non-uniform heat distribution of the substrate 10 varies the concentration of a material growing on the substrate 10. Therefore, for example, when a light emitting diode (LED) is formed on the substrate 10 by growing an epitaxial layer on the substrate 10, the wavelength uniformity characteristics of the LED may be deteriorated.

Therefore, the block part 121 is formed on the bottom side of the pocket 120. When the substrate 10 is placed in the pocket 120, the block part 121 is coupled to the groove 11 of the substrate 10, and thus, a cavity is not formed between the substrate 10 and the pocket 120.

As a result, the substrate 10 may be uniformly heated, and a high-quality epitaxial layer may grow on the substrate 10 uniformly. Therefore, the wavelength non-uniformity of the epitaxial layer may be minimized, and the substrate 10 may have high quality.

Referring to FIG. 2A, the block part 121 protruded on the bottom side of the pocket 120 has a ring shape corresponding to the shape of the groove 11 formed in the bottom side of the substrate 10.

However, the present invention is not limited thereto. That is, as shown in FIG. 2B, a plurality of blocks 122 may be arranged at regular intervals in a ring shape to form a block part 121′.

As shown in FIG. 3, when the substrate 10 is placed in the pocket 120, the block part 121 is coupled to the groove 11 of the substrate 10, and thus an air cavity is not formed by the groove 11.

The substrate 10 may have a single groove 11 as shown in FIG. 3A or a plurality of grooves 11 as shown in FIG. 4A.

According to the positions and number of the grooves 11 formed in the bottom side of the substrate 10, the pocket 120 may include corresponding block parts 121.

As shown in FIG. 4B, the groove 11 may have an arc-shaped cross-section having a gradually curved profile. In this case, the block part 121 may have an arc-shaped cross-section corresponding to the shape of the groove 11.

The cross-sectional shape of the block part 121 of the pocket 120 is not limited to the illustrated rectangular or arc shape. That is, the cross-section shape of the block part 121 may be varied. For example, the block parts 121 may have a triangular shape. The cross-sectional shape of the block part 121 may be determined according to the shape of the groove 11 formed in bottom side of the substrate 10.

As shown in FIGS. 2A through 4B, the pocket 120 may be formed in the top side of the rotary part 110 to a predetermined depth as part of the rotary part 110.

Alternatively, as shown in FIG. 5, the pocket 120 may be provided in a structure separable from the rotary part 110 and rotatable relative to the rotary part 110.

In the case where the pocket 120 is detachably coupled to the rotary part 110, the pocket 120 can be replaced with another pocket 120 according to the size of the substrate 10 and the shape or number of grooves 11 formed in the substrate 10.

Therefore, substrates 10 having various structures and sizes can be processed using the susceptor 100 by replacing only the pocket 120 without having to replace the entire susceptor 100.

In addition, independent of the rotation of the rotary part 110, the pocket 120 can be rotated in the same direction as the rotation direction of the rotary part 110 or in the opposite direction to the rotation direction of the rotary part 110. In this case, a substrate 10 placed in the pocket 120 can rotate on its axis as the pocket 120 rotates, and at the same time, the substrate 10 may revolve around the rotation center of the rotary part 110 as the rotary part 110 rotates, such that an epitaxial layer may be formed on the substrate 10 more uniformly.

The pocket 120 may further include a fixing clip (not shown) to prevent escaping of the substrate 10 from the pocket 120 during rotation.

Examples 30 and 30′ of a CVD apparatus including the above-described susceptor 100 will now be described with reference to the accompanying drawings according to exemplary embodiments of the present invention.

FIG. 6A is a sectional view illustrating a CVD apparatus 30 including a susceptor according to an exemplary embodiment of the present invention, and FIG. 6B is a sectional view illustrating a CVD apparatus 30′ including a susceptor according to another exemplary embodiment of the present invention.

Referring to FIGS. 6A and 6B, each of the CVD apparatus 30 and 30′ includes a reaction chamber 31, a substrate 10, a pocket 120, a susceptor 100, and a heating unit 33.

The reaction chamber 31 has a vertical cylindrical structure and provides a predetermined inner space that can be used for depositing and growing an epitaxial layer on the top side of the substrate 10 (for example, a sapphire substrate) through chemical reaction between the sapphire substrate 10 and reaction gas introduced into the reaction chamber 31 through a gas supply unit 34.

The reaction chamber 31 may be formed of an abrasion-resistant, corrosion-resistant metallic material, and a thermal insulator may be disposed on the inner surface of the reaction chamber 31 for protecting the reaction chamber 31 from a high-temperature atmosphere.

In the reaction chamber 31, the susceptor 100 and the heating unit 33 are disposed. At least one substrate 10 can be mounted on the susceptor 100. An exhaust port 131 is provided at the reaction chamber 31 for discharging gas after the gas chemically reacts with the substrate 10.

As shown in FIG. 6A, the gas supply unit 34 may be disposed at an upper side of the reaction chamber 31 and have a showerhead shape for vertically injecting reaction gas to the upper side of the susceptor 100 which rotates under the gas supply unit 34.

Alternatively, as shown in FIG. 6B, a gas supply unit 34′ may be disposed along the lateral upper end portion of the reaction chamber 31. The gas supply unit may have a planetary structure for horizontally injecting reaction gas into the reaction chamber 31 through a plurality of injection nozzles 35 in directions from the periphery of the reaction chamber 31 toward the center of the reaction chamber 31.

In this case, deposition may proceed while the reaction gas flows from the periphery of the susceptor 100 toward a rotation shaft 130, and then the reaction gas may be discharged from the inside of the reaction chamber 31 through an exhaust port 131 formed in the rotation shaft 130.

In addition, a reverse flow prevention unit (not shown) may be disposed at the exhaust port 131 to prevent a reverse flow of reaction gas from the exhaust port 131 to the inside of the reaction chamber 31 caused by a pressure difference or error.

The pocket 120 includes a block part 121 protruded upward from the bottom side of the pocket 120 at a position corresponding to the position of a groove 11 formed in the bottom side of the substrate 10, so as to uniformly distribute stress when a deposition process is performed in a state where the substrate 10 is placed in the pocket 120 and brought into contact with the bottom side of the pocket 120.

The susceptor 100 may include a plurality of pockets 120 at the top side thereof for performing a deposition process simultaneously on a plurality of substrates 10.

The substrate 10, the pocket 120, and the susceptor 100 including the pocket 120 at its top side are substantially the same as those shown in FIGS. 1 A through 5. Thus, the structures and functions thereof will not be described in detail.

The heating unit 33 is disposed near the bottom side of the susceptor 100 for heating the susceptor 100 where the substrate 10 is placed.

The heating unit 33 may be one of an electric heater, a high-frequency induction heater, an infrared radiation heater, and a laser heater.

A temperature sensor (not shown) may be disposed at the reaction chamber 31 in the vicinity of the susceptor 100 or the heating unit 33 for measuring the inside temperature of the reaction chamber 31 and controlling the heating temperature of the heating unit 33 based on the measured temperature.

In the case where an epitaxial layer such as a gallium nitride (GaN) epitaxial layer, an aluminum nitride (AlN) epitaxial layer, or an indium nitride (InN) epitaxial layer is grown on a sapphire substrate 10 using a CVD apparatus including the above-described susceptor 100, first, the substrate 10 is placed in the pocket 120 disposed at the top side of a rotary part 110 of the susceptor 100.

In this state, the rotary part 110 is rotated by a driving motor (not shown) in a predetermined direction, and group III source gas such as trimethyl gallium (TMGa), triethyl gallium (TEGa), trimethyl indium (TMIn), and trimethyl aluminum (TMAl) is supplied, together with carrier gas such as ammonia, to the inside of the reaction chamber 31 where the rotary part 110 is disposed.

The heating unit 33 disposed under the rotary part 110 is operated to heat the substrate 10. Then, while a mixture (reaction gas) of the source gas and the carrier gas makes contact with the surface of the substrate 10 that rotates together with the rotary part 110 in the predetermined direction, a thin nitride layer (for example, a semiconductor epitaxial layer) is uniformly grown on the surface of the substrate 10, and remaining gas or byproducts flow downward along an inner wall of the reaction chamber 31 and are discharged to the outside.

As described above, the groove 11 is formed in the bottom side of the substrate 10 so as to prevent bending (bowing effect) of the substrate 10 during a layer growing process, and the block part 121 is disposed at the bottom side of the pocket 120 to couple the block part 121 to the groove 11 of the substrate 10 when the substrate 10 is placed in the pocket 120 and brought into contact with the bottom surface of the pocket 120 so as to prevent non-uniform heating of the substrate 10. Therefore, wavelength uniformity of an epitaxial layer formed on the substrate can be maintained. For example, a high-quality substrate product can be manufactured by uniformly forming a high-quality nitride layer on the surface of a substrate.

According to the susceptor and the CVD apparatus including the susceptor, bending (bowing effect) of a larger substrate caused by non-uniform stress distribution may be minimized, and the substrate may be uniformly heated, such that the wavelength uniformity of an epitaxial layer formed on the substrate can be maintained. Therefore, high-quality substrate products can be provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A susceptor for a chemical vapor deposition (CVD) apparatus, the susceptor comprising:
a rotary part configured to be rotated through a rotation shaft connected to a driving device; and
at least one pocket disposed at a top side of the rotary part for receiving a substrate,
wherein the pocket comprises a block part protruded upward from a bottom side of the pocket on which the substrate is placed, the block part being protruded at a position corresponding to a position of a groove, which is formed in a bottom side of the substrate for distributing stress uniformly along the substrate.

2. The susceptor of claim 1, wherein the pocket comprises one or more block parts according to the number and positions of grooves formed in the bottom side of the substrate.

3. The susceptor of claim 1, wherein the block part of the pocket has a ring shape.

4. The susceptor of claim 1, wherein the block part of the pocket comprises a plurality of blocks arranged at predetermined intervals in a ring shape.

5. The susceptor of claim 1, wherein the pocket is separable from the rotary part and rotatable relative to the rotary part.

6. The susceptor of claim 1, wherein the pocket further comprises a fixing clip configured to fix the substrate placed at the pocket for preventing escaping of the substrate when the pocket is rotated.

7. The susceptor of claim 1, wherein the block part of the pocket has a shape corresponding to that of the groove of the substrate for coupling with the groove.

8. A CVD apparatus comprising:
a reaction chamber to which reaction gas is supplied through a gas supply unit for performing a deposition process;
a substrate to which the reaction gas is supplied for depositing an epitaxial layer on a top side of the substrate, the substrate comprising a groove in a bottom side thereof for uniformly distributing stress when the epitaxial layer is deposited;
a pocket at which the substrate is placed, the pocket comprising a block part protruded upward from a bottom side of the pocket that makes contact with the bottom side of the substrate, the block part being protruded at a position corresponding to a position of the groove of the substrate;
a susceptor comprising the pocket at a top side thereof; and
a heating unit disposed at a bottom side of the susceptor for heating the substrate.

9. The CVD apparatus of claim 8, wherein the pocket comprises one or more block parts according to the number and positions of grooves formed in the bottom side of the substrate.

10. The CVD apparatus of claim 8, wherein the block part of the pocket has a ring shape or comprises a plurality of blocks arranged at predetermined intervals in a ring shape.

11. The CVD apparatus of claim 8, wherein the pocket is separable from the susceptor and rotatable relative to the susceptor.

12. The CVD apparatus of claim 8, wherein the block part of the pocket has a shape corresponding to that of the groove of the substrate for coupling with the groove.
